(19) United States
(12) Patent Application Publication
(10) Pub. No.: US 2026/0018881 A1
(43) Pub. Date: Jan. 15, 2026

(54) ELECTROSTATIC DISCHARGE CIRCUIT

(71) Applicant: EMEMORY TECHNOLOGY INC., HSINCHU (TW)

(72) Inventors: YUN-JEN TING, HSINCHU COUNTY (TW); CHIH-WEI LAI, HSINCHU COUNTY (TW); YI-HAN WU, HSINCHU COUNTY (TW); KUN-HSIN LIN, HSINCHU COUNTY (TW); HSIN-KUN HSU, HSINCHU COUNTY (TW)

(21) Appl. No.: 19/243,056

(22) Filed: Jun. 19, 2025

Related U.S. Application Data
(60) Provisional application No. 63/671,307, filed on Jul. 15, 2024.

(51) Int. Cl. H02H 9/02; H02H 3/05; H02H 3/08

(52) U.S. Cl. CPC H02H 9/025; H02H 3/05; H02H 3/08

(57) ABSTRACT

An electrostatic discharge circuit includes a resistor, a capacitor, a first P-type transistor, a first N-type transistor, a first voltage gap provider, a second N-type transistor, and a second voltage gap provider. The resistor and the capacitor coupled in series between the voltage pad and the system voltage. The first P-type transistor, the first voltage gap provider, and the first N-type transistor are coupled in series between the voltage pad and the system voltage with control terminals of the transistors coupled between the resistor and the capacitor. The first voltage gap provider provides a voltage drop between the first P-type transistor and the first N-type transistor. The second voltage gap provider and the second N-type transistor are coupled in series between the voltage pad and the system voltage with a control terminal of the transistor coupled between the first voltage gap provider and the first N-type transistor.

### CROSS REFERENCE

This application claims the benefit of prior-filed U.S. provisional application No. 63/671,307, filed on Jul. 15, 2024, which is incorporated by reference in its entirety.

### TECHNICAL FIELD

The present disclosure relates to an electrostatic discharge (ESD) circuit, and more particularly, to an ESD protection circuit for high voltage operation.

### DISCUSSION OF THE BACKGROUND

Electrostatic discharge (ESD) is a common phenomenon in the field of electronics. Specifically, the ESD occurs when the two electrically charged objects are in contact, the electrical charges in one object will flow to another object through a discharging path. The ESD can generate huge currents in a very short period of time and can damage the integrated circuits (ICs). To protect the ICs from being damaged by the huge ESD current, ESD protection circuits are usually adopted on external pins of the ICs.

In addition, to facilitate the manufacturing, the ESD protection circuits are often manufactured by the low-voltage process that is used to manufacture the ICs they are intended to protect. In such case, the components in the ESD protection circuit can only operate at low voltage during the normal mode. However, some ICs may need to receive high voltage from external pins for certain applications (e.g., the one-time programmable memory may require high voltage for write or erase operations). As a result, components, such as transistors, made by the low-voltage process in the ESD protection circuit may break down, leading to circuit malfunction.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides an electrostatic discharge (ESD) protection circuit coupled between a voltage pad and a circuit to be protected. The ESD protection circuit includes a resistor, a capacitor, a first P-type transistor, a first N-type transistor, a first voltage gap provider, a second N-type transistor, and a second voltage gap provider. The resistor has a first terminal coupled to a voltage pad for receiving a high operation voltage, and a second terminal. The capacitor has a first terminal coupled to the second terminal of the resistor, and a second terminal coupled to a system voltage node for receiving a system voltage lower than the high operation voltage. The first P-type transistor has a first terminal coupled to the voltage pad, a second terminal, and a control terminal coupled to the second terminal of the resistor. The first N-type transistor has a first terminal, a second terminal coupled to the system voltage node, and a control terminal coupled to the second terminal of the resistor. The first voltage gap provider is coupled between the second terminal of the first P-type transistor and the first terminal of the first N-type transistor, and configured to provide a first voltage drop from the second terminal of the first P-type transistor to the first terminal of the first N-type transistor. The second N-type transistor has a first terminal, a second terminal coupled to the system voltage node, and a control terminal coupled to the first terminal of the first N-type transistor. The second voltage gap provider is coupled between the voltage pad and the first terminal of the second N-type transistor, and configured to provide a second voltage drop from the voltage pad to the first terminal of the second N-type transistor. When an electrostatic discharging event with a positive voltage polarity occurs, the second terminal of the resistor is at the system voltage, the first P-type transistor and the second N-type transistor are turned on, the first N-type transistor is turned off, and an ESD current flows from the voltage pad to the second N-type transistor through the second voltage gap provider.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows an electrostatic discharge (ESD) protection circuit according to one embodiment of the present disclosure.

FIG. 2 shows a scenario of the ESD protection circuit in FIG. 1 during a normal mode.

FIG. 3 shows a scenario of the ESD protection circuit in FIG. 1 when an ESD event occurs.

FIG. 4 shows an ESD protection circuit according to another embodiment of the present disclosure.

FIG. 5 shows a scenario of the ESD protection circuit in FIG. 4 during a normal mode.

FIG. 6 shows a scenario of the ESD protection circuit in FIG. 4 when an ESD event occurs.

FIG. 7 shows an ESD protection circuit according to another embodiment of the present disclosure.

### DETAILED DESCRIPTION

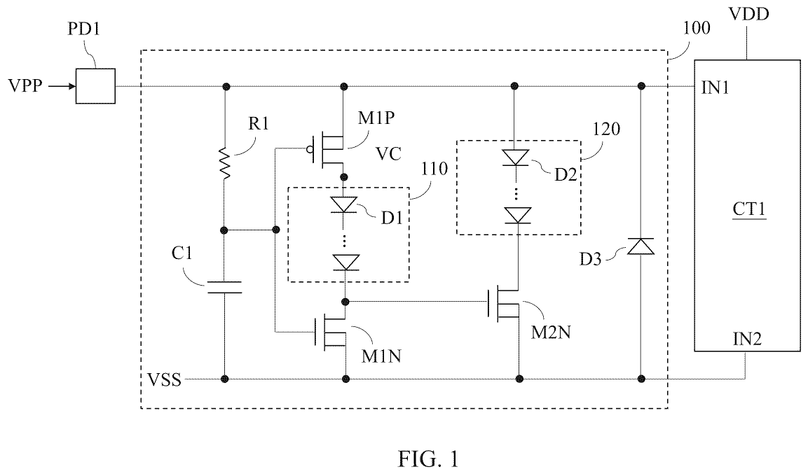

FIG. 1 shows an electrostatic discharge (ESD) protection circuit 100 according to one embodiment of the present disclosure. The ESD protection circuit 100 includes a resistor R1, a capacitor C1, a P-type transistor M1P, an N-type transistor M1N, a drop voltage provider 110, an N-type transistor M2N, and a drop voltage provider 120. In the present embodiment, the ESD protection circuit 100 is disposed between an input terminal IN1 of a circuit CT1 to be protected and a voltage pad PD1 that receives a high operation voltage VPP from an external source. In such case, the ESD protection circuit 100 can protect the circuit CT1 from being damaged by ESD currents, which may be caused when the voltage pad PD1 is coupled to the external source. In some embodiments, the circuit CT1 may include some non-volatile memory cells, and the high operation voltage VPP is for write (i.e. program) or erase operations for the non-volatile memory cells. The circuit CT1 further receives a power supply voltage VDD for read (i.e., a read voltage) operations for the non-volatile memory cells, and the high operation voltage VPP is higher than the power supply voltage VDD.

Furthermore, in the present embodiments, the P-type transistor M1P and the N-type transistors M1N and M2N can be low voltage components that are manufactured by low voltage process. In such case, with the voltage drops provided by the voltage gap providers 110 and 120, the P-type transistor M1P and the N-type transistors M1N and M2N can be operable within their safe operating area (SOA) without being broken down when the circuit CT1 receives the high operation voltage VPP from the voltage pad PD1 during a normal mode even if the high operation voltage VPP is higher than the junction breakdown voltages of the P-type transistor M1P and the N-type transistors M1N and M2N.

As shown in FIG. 1, the resistor R1 has a first terminal coupled to a voltage pad PD1, and a second terminal. The capacitor C1 has a first terminal coupled to the second terminal of the resistor R1, and a second terminal coupled to system voltage node for receiving a system voltage VSS. The system voltage VSS is lower than the high operation voltage VPP, and in some embodiments, the system voltage node can be the ground, the system voltage VSS can be the ground voltage, and the circuit CT1 can also be coupled to the system voltage VSS through the input terminal IN2.

The P-type transistor M1P has a first terminal coupled to the voltage pad PD1, a second terminal, and a control terminal coupled to the second terminal of the resistor R1. The N-type transistor M1N has a first terminal, a second terminal coupled to the system voltage node, and a control terminal coupled to the second terminal of the resistor R1. The voltage gap provider 110 is coupled between the second terminal of the P-type transistor M1P and the first terminal of the N-type transistor M1N. The N-type transistor M2N has a first terminal, a second terminal coupled to the system voltage node, and a control terminal coupled to the first terminal of the N-type transistor M1N. The voltage gap provider 120 is coupled between the voltage pad PD1 and the first terminal of the N-type transistor M2N.

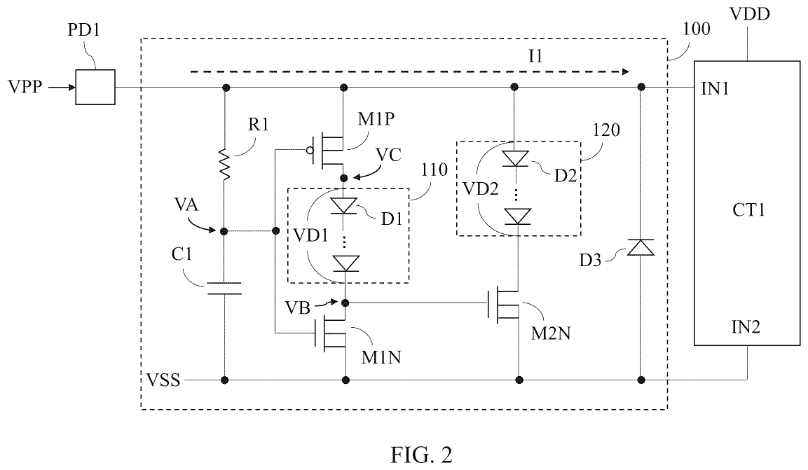

FIG. 2 shows a scenario of the ESD protection circuit 100 during a normal mode. During the normal mode, the voltage pad PD1 receives the high operation voltage VPP. In such case, the capacitor C1 is charged and the voltage VA of the second terminal of the resistor R1 is at the high operation voltage VPP, and thus, the N-type transistor M1N is turned on, and the P-type transistor M1P is turned off. Accordingly, the voltage VB of the first terminal of the N-type transistor M1N is pulled down to the system voltage VSS, thereby turning off the N-type transistor M2N. As a result, the charging current I1 can flow from the voltage pad PD1 to the input terminal IN1 of the circuit CT1, allowing the input terminal IN1 of the circuit CT1 to receive the high operation voltage VPP in the normal mode.

In the present embodiment, the voltage gap provider 110 can provide a voltage drop VD1 from the second terminal of the P-type transistor M1P to the first terminal of the N-type transistor M1N, so that the voltage VC of the second terminal of the P-type transistor M1P is at a voltage equal to the system voltage VSS plus the voltage drop VD1. As a result, the cross voltage applied between the first terminal and the second terminal of the P-type transistor M1P is VPP minus voltage drop VD1. In the present embodiment, the voltage drop VD1 is high enough to ensure the cross voltage applied between the first terminal and the second terminal of the P-type transistor M1P to be smaller than the break down voltage of the P-type transistor M1P. For example, if the break down voltage of the P-type transistor M1P is 9V and the high operation voltage VPP is 10V, then the voltage drop VD1 provided by the voltage gap provider 110 can be 1.8V. Consequently, the cross voltage applied between the first terminal and the second terminal of the P-type transistor M1P would be 8.2V, which is smaller than the break down voltage of the P-type transistor M1P, thereby protecting the P-type transistor M1P from being broken down.

In addition, the voltage gap provider 120 can provide a voltage drop VD2 from the voltage pad PD1 to the first terminal of the second N-type transistor M2N, and thus, the cross voltage applied between the first terminal and the second terminal of the N-type transistor M2N would be VPP minus voltage drop VD2. In the present embodiment, the voltage drop VD2 is high enough to ensure the cross voltage applied between the first terminal and the second terminal of the N-type transistor M2N to be smaller than the break down voltage of the N-type transistor M2N. For example, if the break down voltage of the N-type transistor M2N is 9V, then the voltage drop VD2 provided by the voltage gap provider 120 can be 1.8V. Consequently, the cross voltage applied between the first terminal and the second terminal of the N-type transistor M2N would be 8.2V, which is smaller than the break down voltage of the N-type transistor M2N, thereby protecting the N-type transistor M2N from being broken down.

In the present embodiment, the voltage gap provider 110 may include at least one diode D1 coupled in series. In some embodiments, the number of diodes D1 in the voltage gap provider 110 can be determined by the desired voltage drop VD1. For example, if the desired voltage drop VD1 to be provided is 1.8V, and the turn-on voltage of a diode D1 is 0.6V, then the voltage drop provide 110 may include three diodes D1.

Similarly, the voltage gap provider 120 may include at least one diode D2 coupled in series, and the number of diodes D2 in the voltage gap provider 120 can be determined by the desired voltage drop VD2.

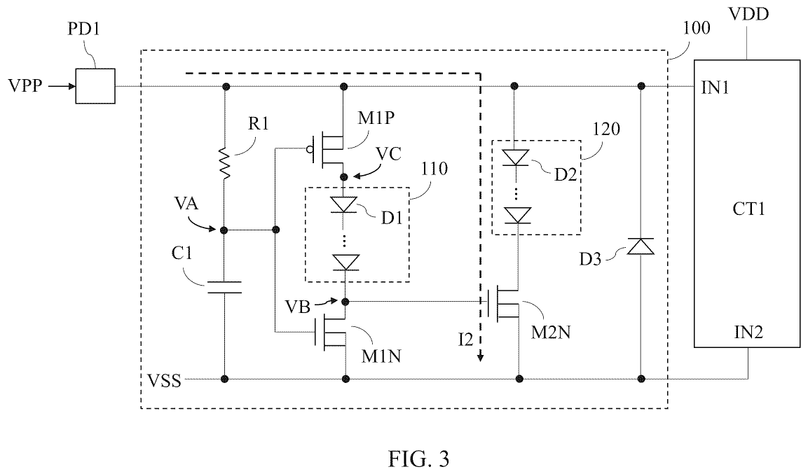

FIG. 3 shows a scenario of the ESD protection circuit 100 when an ESD event occurs. When the ESD event with a positive voltage polarity occurs, the capacitor C1 may behave as a shorted circuit, and the voltage VA of the second terminal of the resistor R1 can be pulled down to the system voltage VSS, thereby turning on the P-type transistor M1P and turning off the N-type transistor M1N. In such case, the voltage VB of the first terminal of the N-type transistor M1N is raised to a high voltage through the P-type transistor M1P and the voltage gap provider 110, and thus, the N-type transistor M2N is turned on. As a result, the ESD current I2 can be bypassed to the low impedance path formed by the voltage gap provider 120 and the N-type transistor M2N without entering the input terminal IN1 of the circuit CT1.

In the present embodiment, an anode of each of the diodes D1 is coupled to the second terminal of the P-type transistor M1P or a cathode of another diode D1, and a cathode of each of the diodes D1 is coupled to the first terminal of the N-type transistor M1N or an anode of another diode D1. Also, an anode of each of the diodes D2 is coupled to the voltage pad PD1 or a cathode of another diode D2, and a cathode of each of the diodes D2 is coupled to the first terminal of the second N-type transistor M2N or an anode of another diode D2. In such case, the discharging path provided by the voltage gap provider 120 and the N-type transistor M2N is directional and only allows the ESD currents in a forward direction (i.e., from the voltage pad PD1 to the ground) to pass. Therefore, when an electrostatic discharging event with a negative voltage polarity occurs, to provide a discharging path for a reversed direction (i.e., from the system voltage node to the voltage pad PD1), the ESD protection circuit 100 further includes at least one diode D3 coupled in series between the voltage pad PD1 and the system voltage VSS. In the present embodiment, an anode of the diode D3 is coupled to the system voltage node, and a cathode of the diode D3 is coupled to the voltage pad PD1. In some embodiments, the diode D3 can be a parasitic capacitor that is formed by P-wells and N-wells of transistors in the ESD protection circuit 100 so as to reduce the circuit area. However, the present disclosure is not limited thereto.

Furthermore, in some embodiments, since the ESD currents may flow through the diodes D2 or D3, the diodes D2 and D3 may have to endure higher current rating. Therefore, the diodes D2 and D3 may be designed to have greater sizes than the size of the diode D1. Similarly, since the ESD currents may flow through the N-type transistor M2N, the size of the N-type transistor M2N can be greater than the size of the N-type transistor M1N and the size of the P-type transistor M1P.

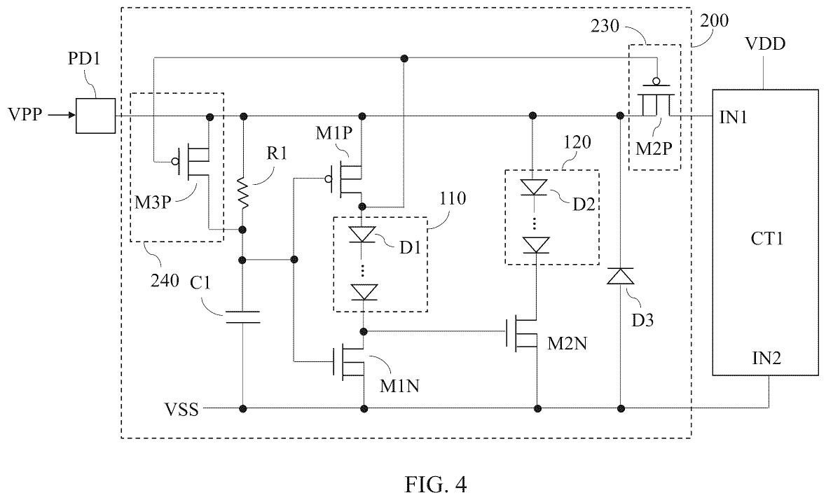

FIG. 4 shows an ESD protection circuit 200 according to another embodiment of the present disclosure. The ESD protection circuit 200 is different from the ESD protection circuit 100 in that the ESD protection circuit 200 further includes a protection switch 230 and a latch unit 240.

The protection switch 230 is coupled between the voltage pad PD1 and an input terminal IN1 of a circuit CT1 to be protect. The protection switch 230 can cut off an electrical connection between the voltage pad PD1 and the input terminal IN1 when the ESD event occurs so as to protect the circuit CT1 from receiving the drastic and huge ESD current.

In the present embodiment, the protection switch 230 includes a P-type transistor M2P having a first terminal coupled to the voltage pad PD1, a second terminal coupled to the input terminal IN1 of the circuit CT1, and a control terminal coupled to the second terminal of the P-type transistor M1P.

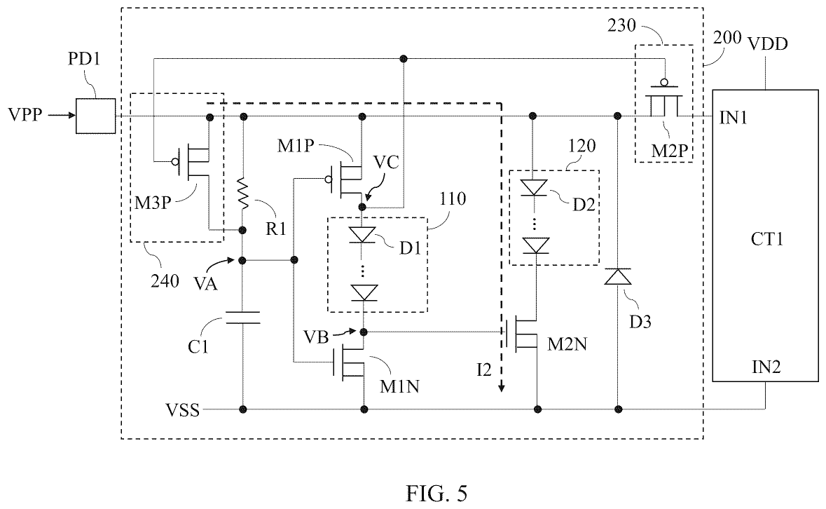

FIG. 5 shows a scenario of the ESD protection circuit 100 when an ESD event occurs. As shown in FIG. 5, when the ESD event occurs, since the voltage VC of the second terminal of the P-type transistor M1P is raised to a high voltage, the P-type transistor M2P would be turned off, thereby avoiding the ESD current from entering the circuit CT1.

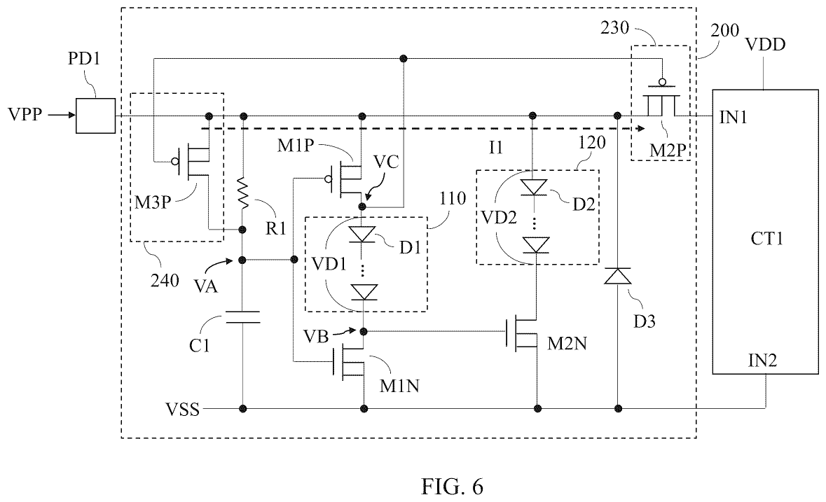

FIG. 6 shows a scenario of the ESD protection circuit 200 during a normal mode. As shown in FIG. 6, when the ESD protection circuit 200 works in the normal mode, the voltage VC of the second terminal of the P-type transistor M1P would be pulled down, and thus the P-type transistor M2P would be turned on, thereby allowing the input terminal IN1 to receive the high operation voltage VPP. It may also be noted that, due to the properly designated voltage drop VD1 provided by the voltage gap provider 110, the cross voltage applied to first terminal and the second terminal of the P-type transistor M2P can also be lower than its breakdown voltage, thereby allowing the P-type transistor M2P to operate in its SOA.

The latch unit 240 is coupled between the voltage pad PD1 and the second terminal of the resistor R1. In the present embodiment, the ESD event happens when the voltage pad PD1 is coupled to the high operation voltage VPP, and after such ESD event, the ESD protection circuit 200 should keep operating in the normal mode. However, when the high operation voltage VPP is adopted to perform certain operations by the circuit CT1, the high operation voltage VPP may fluctuate due to the load change. Such voltage fluctuation may trigger the ESD protection circuit 200 to turn on the N-type transistor M2N and form the discharging path. As a result, the circuit CT1 would not be able to receive the high operation voltage VPP as needed. To solve this issue, the latch unit 240 can hold the voltage VA of the second terminal of the resistor R1 at the high operation voltage VPP once the ESD protection circuit 200 enters the normal mode after the ESD event, so the P-type transistor M1P can be kept turned off and the N-type transistor M1N can be kept turned on, thereby preventing the N-type transistor M2N from mistakenly turned on.

As shown in FIG. 6, the latch unit 240 can include a P-type transistor M3P having a first terminal coupled to the voltage pad PD1, a second terminal coupled to the second terminal of the resistor R1, and a control terminal coupled to the second terminal of the P-type transistor M1P. It may be noticed that, due to the voltage drop VD1 provided by the voltage gap provider 110, the cross voltage applied to first terminal and the second terminal of the P-type transistor M3P can also be lower than its breakdown voltage, allowing the P-type transistor M3P to operate in its SOA when the ESD protection circuit 200 is in the normal mode.

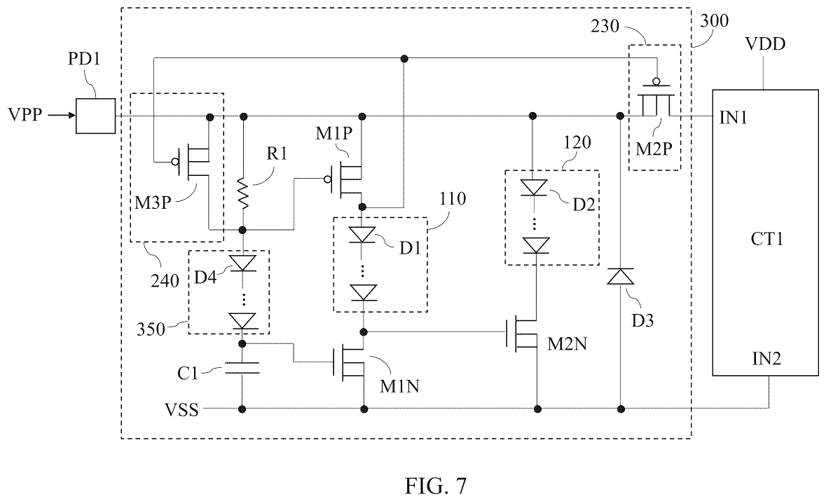

FIG. 7 shows an ESD protection circuit 300 according to another embodiment of the present disclosure. The ESD protection circuit 300 is different from the ESD protection circuit 200 in that the ESD protection circuit 300 further includes a voltage gap provider 350 having a first terminal and a second terminal. The first terminal of the voltage gap provider 350 is coupled to the second terminal of the transistor M3P, the second terminal of the resistor R1, and the control terminal of the P-type transistor M1P. The second terminal of the voltage gap provider 350 is coupled to the first terminal of the capacitor Cl and the control terminal of the N-type transistor M1N. The voltage gap provider 350 can provide a voltage drop from the control terminal of the P-type transistor M1P to the control terminal of the N-type transistor M1N so as to ensure the transistors M1N and M1P to be operable within their safe operating area (SOA). Consequently, even if the gate oxides of transistors M1P and M1N are relatively thin (whether due to process variation or intentional process choices), the voltage gap provider 350 can help to protect the transistors M1P and M1N from being broken down during operations.

In the present embodiments, the voltage gap provider 350 may include at least one diode D4 coupled in series between the first terminal and the second terminal of the voltage gap provider 350. Specifically, an anode of each of the diodes D4 is coupled to the first terminal of the voltage gap provide 350 or a cathode of another diode D4, and a cathode of each of the diodes D4 is coupled to the second terminal of the voltage gap provide 350 or an anode of another diode D2.

In such case, the voltage drop is equal to a summation voltage of a turn-on voltage of each diode D4. In some embodiments, in the normal mode, the voltage drop provided by the voltage gap provider 350 is high enough to ensure a voltage between the control terminal and the second terminal of the N-type transistor M1N to be smaller than the break down voltage of the N-type transistor M1N. Also, during the electrostatic discharging event, the voltage drop provided by the voltage gap provider 350 is high enough to ensure a voltage between the control terminal and the first terminal of the P-type transistor M1P to be smaller than the break down voltage of the P-type transistor M1P.

In summary, the ESD protection circuit provided by the embodiments of the present disclosure allows the low voltage components therein to operate under high-voltage conditions while effectively protecting the circuit from being damaged by the ESD currents.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. An electrostatic discharge (ESD) protection circuit coupled between a voltage pad and a circuit to be protected, and the ESD protection circuit comprising:
a resistor having a first terminal coupled to the voltage pad for receiving a high operation voltage, and a second terminal;
a capacitor having a first terminal coupled to the second terminal of the resistor, and a second terminal coupled to a system voltage node for receiving a system voltage lower than the high operation voltage;
a first P-type transistor having a first terminal coupled to the voltage pad, a second terminal, and a control terminal coupled to the second terminal of the resistor;
a first N-type transistor having a first terminal, a second terminal coupled to the system voltage node, and a control terminal coupled to the second terminal of the resistor;
a first voltage gap provider coupled between the second terminal of the first P-type transistor and the first terminal of the first N-type transistor, and configured to provide a first voltage drop from the second terminal of the first P-type transistor to the first terminal of the first N-type transistor;
a second N-type transistor having a first terminal, a second terminal coupled to the system voltage node, and a control terminal coupled to the first terminal of the first N-type transistor; and
a second voltage gap provider coupled between the voltage pad and the first terminal of the second N-type transistor, and configured to provide a second voltage drop from the voltage pad to the first terminal of the second N-type transistor;
wherein when an electrostatic discharging event with a positive voltage polarity occurs, the second terminal of the resistor is at the system voltage, the first P-type transistor and the second N-type transistor are turned on, the first N-type transistor is turned off, and an ESD current flows from the voltage pad to the second N-type transistor through the second voltage gap provider.

2. The ESD protection circuit of claim 1, further comprising a protection switch coupled between the voltage pad and an input terminal of the circuit to be protected and configured to cut off an electrical connection between the voltage pad and the input terminal when the electrostatic discharging event occurs.

3. The ESD protection circuit of claim 2, wherein the protection switch comprises a second P-type transistor having a first terminal coupled to the voltage pad, a second terminal coupled to the input terminal of the circuit to be protected, and a control terminal coupled to the second terminal of the first P-type transistor, and when the electrostatic discharging event with the positive voltage polarity occurs, the second terminal of the first P-type transistor is at a high voltage to turn off the protection switch to cut off the electrical connection.

4. The ESD protection circuit of claim 1, further comprising a latch unit coupled between the voltage pad and the second terminal of the resistor, and configured to hold a voltage of the second terminal of the resistor at the high operation voltage in a normal mode so as to keep the first P-type transistor turned off and keep the first N-type transistor turned on.

5. The ESD protection circuit of claim 4, wherein the latch unit comprises a third P-type transistor having a first terminal coupled to the voltage pad, a second terminal coupled to the second terminal of the resistor, and a control terminal coupled to the second terminal of the first P-type transistor, wherein in the normal mode after the electrostatic discharging event, the capacitor is charged and the second terminal of the resistor is at a high voltage to turn on the first N-type transistor, a first terminal of the first N-type transistor is at the system voltage, and the second terminal of the first P-type transistor is at a voltage equal to the system voltage plus the first voltage drop to turn on the third P-type transistor.

6. The ESD protection circuit of claim 1, wherein the first voltage gap provider comprises at least one first diode coupled in series, and the first voltage drop is equal to a summation voltage of a turn-on voltage of each first diode.

7. The ESD protection circuit of claim 6, wherein the second voltage gap provider comprises at least one second diode coupled in series, and the second voltage drop is equal to a summation voltage of a turn-on voltage of each second diode.

8. The ESD protection circuit of claim 7, further comprising at least one third diode coupled in series between the voltage pad and the system voltage node, when an electrostatic discharging event with a negative voltage polarity occurs, the third diode provide an ESD current discharging path from the system voltage node to the voltage pad.

9. The ESD protection circuit of claim 8, wherein:
an anode of the at least one second diode is coupled to the voltage pad, and a cathode of the at least one second diode is coupled to the first terminal of the second N-type transistor; and
an anode of the at least one third diode is coupled to the system voltage node, and a cathode of the at least one third diode is coupled to the voltage pad.

10. The ESD protection circuit of claim 9, wherein a size of the at least one third diode and a size of the at least one second diode are greater than a size of the at least one first diode.

11. The ESD protection circuit of claim 9, wherein the at least one third diode is a parasitic capacitor formed by a P-well and an N-well of transistors in the ESD protection circuit.

12. The ESD protection circuit of claim 1, wherein a size of the second N-type transistor is greater than a size of the first N-type transistor and a size of the first P-type transistor.

13. The ESD protection circuit of claim 1, wherein during a normal mode after the electrostatic discharging event, the second terminal of the resistor is at the high operation voltage supplied from the voltage pad, the first N-type transistor is turned on, the first P-type transistor and the second N-type transistor are turned off, and the first voltage drop is high enough to ensure a voltage between the first terminal of the first P-type transistor and the second terminal of the first P-type transistor to be smaller than a break down voltage of the first P-type transistor.

14. The ESD protection circuit of claim 13, wherein during the normal mode, the second voltage drop is high enough to ensure a voltage between the first terminal of the second N-type transistor and the second terminal of the second N-type transistor to be smaller than a break down voltage of the second N-type transistor.

15. The ESD protection circuit of claim 14, wherein the circuit to be protected comprises a memory cell, and the high operation voltage is for programing the memory cell and the high operation voltage is higher than a read voltage for reading the memory cell.

16. The ESD protection circuit of claim 15, further comprising a third P-type transistor having a first terminal coupled to the voltage pad, a second terminal coupled to the second terminal of the resistor, and a control terminal coupled to the second terminal of the first P-type transistor, and configured to hold a voltage of the second terminal of the resistor at the high operation voltage in a normal mode so as to keep the first P-type transistor turned off and keep the first N-type transistor turned on, and wherein:
the first voltage gap provider comprises at least one first diode coupled in series, and the first voltage drop is equal to a summation voltage of a turn-on voltage of each first diode, and the second voltage gap provider comprises at least one second diode coupled in series, and the second voltage drop is equal to a summation voltage of a turn-on voltage of each second diode.

17. The ESD protection circuit of claim 16, further comprising at least one third diode coupled in series between the voltage pad and the system voltage, when an electrostatic discharging event with a negative voltage polarity occurs, the third diode provide an ESD current discharging path from the system voltage node to the voltage pad.

18. The ESD protection circuit of claim 16, further comprising a third voltage gap provider having a first terminal and a second terminal, wherein:
the first terminal of the third voltage gap provider is coupled to the second terminal of the third P-type transistor, the second terminal of the resistor, and the control terminal of the first P-type transistor, and the second terminal of the third voltage gap provider is coupled to the first terminal of the capacitor and the control terminal of the first N-type transistor;
the third voltage gap provider is configured to provide a third voltage drop from the control terminal of the first P-type transistor to the control terminal of the first N-type transistor; and
the third voltage gap provider comprises at least one fourth diode coupled in series between the first terminal and the second terminal of the third voltage gap provider, and the third voltage drop is equal to a summation voltage of a turn-on voltage of each fourth diode.
